(19) United States
(12) Patent Application Publication
(10) Pub. No.: US 2020/0295240 A1
(43) Pub. Date: Sep. 17, 2020

(54) LIGHT-EMITTING SEMICONDUCTOR DEVICE

(71) Applicant: OSRAM OPTO SEMICONDUCTORS GMBH, Regensburg (DE)

(72) Inventors: Alexander LINKOV, Herzogenrath (DE); Hubert HALBRITTER, Dietfurt (DE)

(21) Appl. No.: 16/651,218

(22) PCT Filed: Dec. 11, 2018
(86) PCT No.: PCT/EP2018/084352

§ 371 Date: Mar. 26, 2020

(30) Foreign Application Priority Data
Dec. 12, 2017 (DE) 10 2017 129 623.9

(51) Int. Cl. H01L 33/50; H01L 33/60; H01L 33/42

(52) U.S. Cl. CPC H01L 33/505; H01L 33/42; H01L 33/60

(57) ABSTRACT

A light-emitting semiconductor device is specified which comprises a light-emitting semiconductor chip having a main surface comprising a radiation-outcoupling surface via which, during operation, a first light in a first wavelength range is emitted. A wavelength conversion layer for converting at least part of the first light into second light in a second wavelength range different from the first wavelength range is applied onto a first sub-region of the main surface. An optical feedback element is applied directly to a second sub-region of the main surface adjacent to the first sub-region, wherein the optical feedback element deflects first light emitted from the second sub-region in the direction of the radiation-outcoupling surface and/or in the direction of the wavelength conversion layer.

A light-emitting semiconductor device is specified.

This patent application claims the priority of the German patent application 10 2017 129 623.9, the disclosure content of which is hereby included by reference.

In order to generate white light by means of a light-emitting diode chip, to the light-emitting diode chip that generates short-wave light such as blue light a conversion material is usually applied, which converts part of the short-wave light into longer-wave light. However, the luminous density distribution of such an arrangement is negatively influenced by the random directional emission of the conversion material in combination with the usually Lambertian radiation characteristic of the light-emitting diode chip. In particular, this combination results in the white light having an inhomogeneous and thus unfavorable luminous density distribution. In order to homogenize the luminous density distribution, apertures or reflectors on the converter are usually used to narrow the angular distribution of the white light.

At least one object of particular embodiments is to provide a light-emitting semiconductor device.

This object is achieved by a subject-matter according to the independent claim. Advantageous embodiments and developments of the subject-matter are characterized in the dependent claims, and are also disclosed by the following description and the drawings.

According to at least one embodiment, a light-emitting semiconductor device comprises a light-emitting semiconductor chip. The light-emitting semiconductor chip comprises in particular a semiconductor layer sequence with an active region for generating light. The active region can in particular have an active layer in which the light is generated during operation. The light generated by the light-emitting semiconductor chip during operation can also be referred to here and in the following as first light. The semiconductor layer sequence can be produced particularly preferably by means of an epitaxy process, for example by metal organic vapor phase epitaxy (MOVPE) or molecular beam epitaxy (MBE). The semiconductor layer sequence thus comprises semiconductor layers which are arranged one above the other along an arrangement direction in a vertical direction given by the growth direction. Perpendicular to the vertical direction, the layers of the semiconductor layer sequence each have a main extension plane. Directions parallel to the main extension plane of the semiconductor layers are hereinafter referred to as lateral directions.

The light-emitting semiconductor chip comprises a main surface which can be arranged perpendicular to the growth direction of the semiconductor layer sequence with a main extension plane in the lateral direction and which comprises a radiation-outcoupling surface via which the first light generated in the semiconductor chip during operation is emitted. In particular, the radiation-outcoupling surface can be the main surface of the semiconductor chip. Furthermore, the light-emitting semiconductor chip comprises a rear side opposite the main surface and thus opposite the radiation-outcoupling surface. The main surface and the rear side can be connected to each other by chip side surfaces which delimit the semiconductor chip in lateral direction. The rear side surface or one of the side surfaces can form a mounting surface with which the semiconductor chip can be arranged on a carrier, for example. Together with the side surfaces, the main surface can form an edge that delimits the main surface in the lateral direction. Regions of the main surface that comprise at least part of the edge of the main surface can be called edge regions here and in the following.

Depending on the first light to be generated, the light-emitting semiconductor chip can have a semiconductor layer sequence based on different semiconductor material systems. For long-wave, infrared to red radiation for example a semiconductor layer sequence based on InₓGa_{y}Al_{1-x-y}As is suitable, for red to green radiation for example a semiconductor layer sequence based on InₓGa_{y}Al_{1-x-y}P is suitable, and for short-wave visible radiation, i.e. in particular for green to blue radiation, and/or for UV radiation for example a semiconductor layer sequence based on InₓGa_{y}Al_{1-x-y}N is suitable, wherein 0≤x≤1 and 0≤y≤1 apply in each case. For electrical contacting, the light-emitting semiconductor chip can have contact layers by means of which an electric current for light generation can be injected into the semiconductor layer sequence during operation. In addition, further layers and elements can be present, for example a substrate on which the semiconductor layer sequence is applied, passivation layers and/or mirror layers. The light-emitting semiconductor chip can, for example, be embodied as a so-called volume emitter, a thin-film semiconductor chip or a flip chip. The design, structure and function of light-emitting semiconductor chips are known to experts and are therefore not explained in detail here.

According to a further embodiment, the light-emitting semiconductor device comprises a wavelength conversion layer which is arranged on the main surface of the light-emitting semiconductor chip. In particular, the wavelength conversion layer is arranged on the radiation-outcoupling surface. The fact that the wavelength conversion layer is arranged on the main surface and on the radiation-outcoupling surface can mean that the wavelength conversion layer is applied directly onto the main surface of the semiconductor chip and in particular also directly onto the radiation-outcoupling surface. For this purpose, the wavelength conversion layer can, for example, be attached to the radiation-outcoupling surface of the light-emitting semiconductor chip by means of a suitable bonding layer, such as an adhesive layer, or also be formed directly on the main surface. If the light-emitting semiconductor chip comprises on the radiation-outcoupling surface an electrode layer, which is electrically contacted by means of a bond wire connection, for example, the wavelength conversion layer can have a recess at this position. Furthermore, it can also be possible for the wavelength conversion layer to be arranged at a distance from the main surface and in particular at a distance from the radiation-outcoupling surface. In this case, a further element or layer can be arranged on the main surface of the semiconductor chip, especially the optical feedback element described below, with the wavelength conversion layer being arranged on the further element or layer.

The wavelength conversion layer can have a bottom side facing the radiation-outcoupling surface of the light-emitting semiconductor chip, a top side opposite the bottom side, and side surfaces connecting the bottom side to the top side. The wavelength conversion layer is thus arranged vertically downstream of the light-emitting semiconductor chip in the beam path of the first light and is delimited laterally by the side surfaces.

The wavelength conversion layer can comprise at least one or more wavelength conversion materials suitable for at least partially converting the first light emitted by the light-emitting semiconductor chip during operation into a light of a different wavelength, hereinafter also referred to as second light, so that the light-emitting semiconductor device can emit a mixed light of the first light emitted primarily by the semiconductor chip and the converted second light or, in the case of a complete conversion of the first light emitted by the semiconductor chip, substantially the converted second light.

For example, the wavelength conversion material or materials can comprise one or more of the following: rare earth and alkaline earth metals, nitrides, nitride-silicates, sions, sialons, aluminates, oxides, halophosphates, orthosilicates, sulphides, vanadates and chlorosilicates. Furthermore, the wavelength conversion material(s) can additionally or alternatively comprise an organic material which can be selected from a group comprising perylenes, benzopyrenes, coumarins, rhodamines and azo dyes. For example, the wavelength conversion material(s) can be contained in a transparent matrix material which can be formed by a plastic such as silicone, by a glass, by a ceramic material or by a combination thereof. This can form a so-called phosphor platelet as a wavelength conversion layer, which can be prefabricated and can thus be self-supporting, or can be formed by applying it to the main surface. Furthermore, the wavelength conversion material(s) can be deposited on a transparent substrate, such as a glass or ceramic substrate. In addition, a ceramic wavelength conversion material can also be a self-supporting ceramic component that forms the wavelength conversion layer.

According to a further embodiment, the wavelength conversion layer does not cover the entire main surface and in particular not the entire radiation-outcoupling surface of the light-emitting semiconductor chip. Rather, the wavelength conversion layer is arranged particularly preferably on a first sub-region of the main surface, which is in particular a sub-region of the radiation-outcoupling surface. The part of the wavelength conversion layer which is arranged in the vertical direction above the first sub-region can, particularly preferably, be illuminated directly with first light and be a projection of the first sub-region on a side of the wavelength conversion layer facing the semiconductor chip. The first sub-region can preferably not comprise any edge region of the main surface. In other words, the first sub-region can be spaced from the edge of the first main surface on all sides.

According to a further embodiment, the light-emitting semiconductor device comprises an optical feedback element. The optical feedback element is applied in particular to the main surface, preferably directly thereon. In particular, the optical feedback element can be applied to the radiation-outcoupling surface and preferably directly on this surface. Furthermore, the optical feedback element does not completely cover the main surface of the light-emitting semiconductor chip and in particular the radiation-outcoupling surface. Rather, the optical feedback element is arranged on a second sub-region of the main surface adjacent to the first sub-region and at least partially different from the first sub-region. The first and second sub-regions can partially overlap in the lateral direction or can also directly adjoin one another without overlap.

According to a further embodiment, the optical feedback element deflects first light emitted from the second sub-region towards the radiation-outcoupling surface and/or towards the wavelength conversion layer. Furthermore, the optical feedback element can also deflect light radiated from the first sub-region in a region vertically above the second region towards the radiation-outcoupling surface and/or towards the wavelength conversion layer. For example, first light radiated in a direction, along which the first light would miss the wavelength conversion layer in the absence of the optical feedback element or along which the first light would be radiated at an undesirably large angle, can be deflected towards the radiation-outcoupling surface and/or towards the wavelength conversion layer.

Furthermore, the second sub-region can be an edge region of the main surface, wherein the second sub-region can also completely surround the first sub-region in lateral direction. In other words, when the main surface is viewed along the vertical direction, the second sub-region can form a frame around the first sub-region.

The first and second sub-regions can particularly preferably form the main surface. In particular, the main surface can be completely formed by the first and second sub-regions, so that the main surface is completely covered by the combination of the wavelength conversion layer or the optical feedback element. In particular, the wavelength conversion layer and the optical feedback element do not or only insignificantly protrude in lateral direction beyond the main surface of the light-emitting semiconductor chip. “Only insignificantly protruding” can in particular mean that the wavelength conversion layer and/or the optical feedback element protrude in the lateral direction by less than a maximum lateral extension of the main surface or by less than 10% of a maximum lateral extension of the main surface in the lateral direction beyond the main surface.

Particularly preferably, the light-emitting semiconductor chip, the wavelength conversion layer and the optical feedback element, if necessary with further layers or elements such as, for example, connecting layers, form a self-supporting, coherent component whose lateral extension is determined at least substantially, i.e. in the manner described above, by the lateral extension of the light-emitting semiconductor chip. In particular, the wavelength conversion layer and the optical feedback element can be elements of the light-emitting semiconductor device which are attached to the light-emitting semiconductor chip, so that the light-emitting semiconductor chip together with the wavelength conversion layer and the optical feedback element can be mounted, with the rear side of the light-emitting semiconductor chip, as one coherent component on an external carrier such as a housing.

According to a further embodiment, the wavelength conversion layer is directly adjacent to the optical feedback element. This can mean that the optical feedback element is directly adjacent to one side surface, preferably all side surfaces, of the wavelength conversion layer. The wavelength conversion layer and the optical feedback element can also be manufactured together and arranged as a common component on the main surface of the previously provided light-emitting semiconductor chip.

The light-emitting semiconductor device can be manufactured in particular in a compound. For this purpose, a semiconductor wafer can be provided with a plurality of semiconductor chips that have not yet been singulated. A plurality of wavelength conversion layers and a plurality of optical feedback elements can be applied to the semiconductor wafer, wherein the plurality of wavelength conversion layers and/or the plurality of optical feedback elements can be applied individually or as a coherent compound. Subsequently, a singulation in single light-emitting semiconductor devices can be carried out by dividing the semiconductor wafer with the applied wavelength conversion layers and optical feedback elements.

According to a further embodiment, the optical feedback element comprises one or more elements that are capable of deflecting light, especially first light. Particularly preferably, the optical feedback element can comprise one or more elements selected from a diffractive optical element, gradient optics, a photonic crystal and a reflective optical element. Combinations of the mentioned elements and their optical properties can also be possible. For example, the optical feedback element can comprise a reflective optical element having a reflecting layer which is inclined with respect to a surface normal of the main surface and/or which is curved. The reflecting layer can, for example, comprise a metal and/or a dielectric layer sequence, in particular in the form of a Bragg mirror, or can be formed thereof. If the reflecting layer is curved, the curvature can be, for example, parabolic, hyperbolic, elliptical or a combination thereof. Furthermore, the optical feedback element can comprise a transparent material on which the reflecting layer is deposited. The transparent material can, for example, comprise or be made of a plastic such as epoxy and/or a glass.

By means of the optical feedback element, which can be an angle-selective feedback element in accordance with the above-mentioned embodiments, the radiation characteristic of the light-emitting semiconductor chip can be altered and optimized. Since the optical feedback element can be arranged on a sub-region, in particular an edge region, of the main surface that is at least partially different from sub-region with the wavelength conversion layer, an area, which is smaller in comparison to the entire main surface, with the wavelength conversion layer can be optically pumped which would not be possible without the optical feedback element, but wherein the area is pumped with a higher luminous density. As a result, the light-emitting semiconductor device can emit the first and second light with a higher total luminous density per effective area. This effect can be achieved by means of a higher integration density at system level, especially by using smaller and more compact optics compared to conventional solutions.

Further advantages, advantageous embodiments and further developments are revealed by the embodiments described below in connection with the figures, in which:

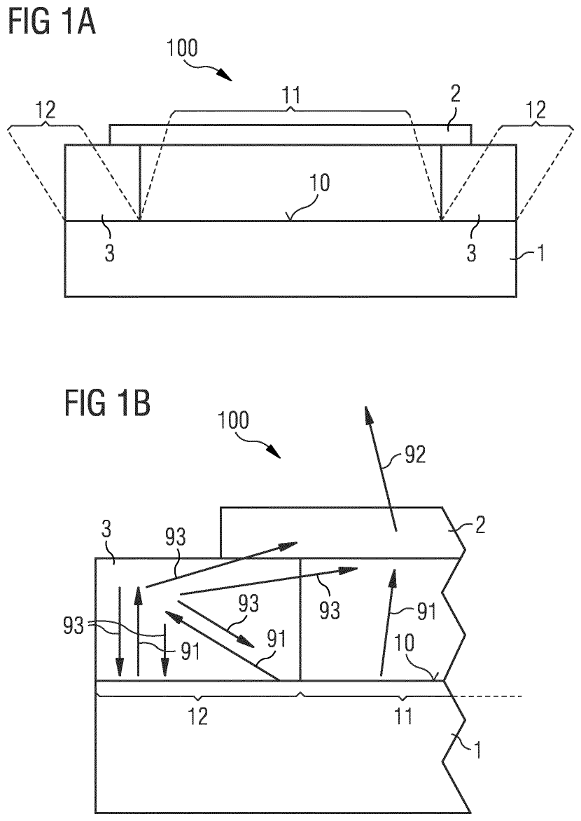

FIGS. 1A and 1B show schematic illustrations of a light-emitting semiconductor device according to an embodiment,

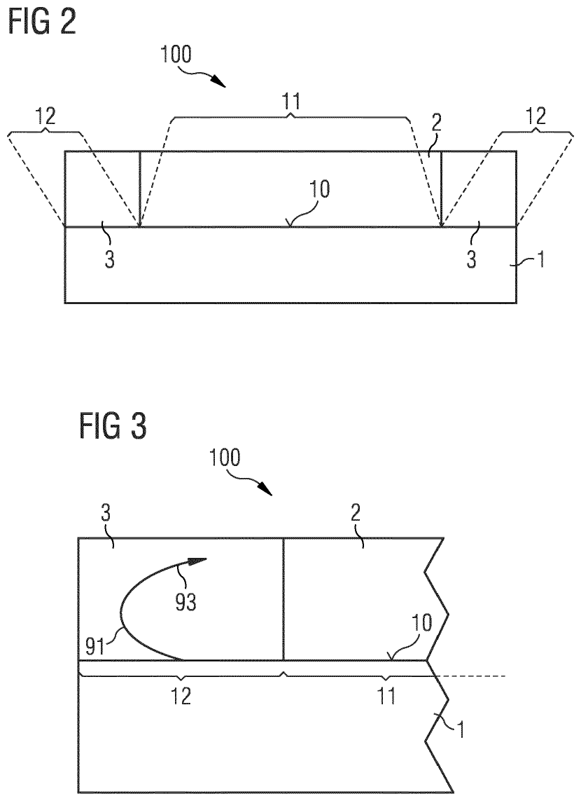

FIG. 2 shows a schematic illustration of light-emitting semiconductor device according to a further embodiment,

FIG. 3 shows a schematic illustration of light-emitting semiconductor device according to a further embodiment,

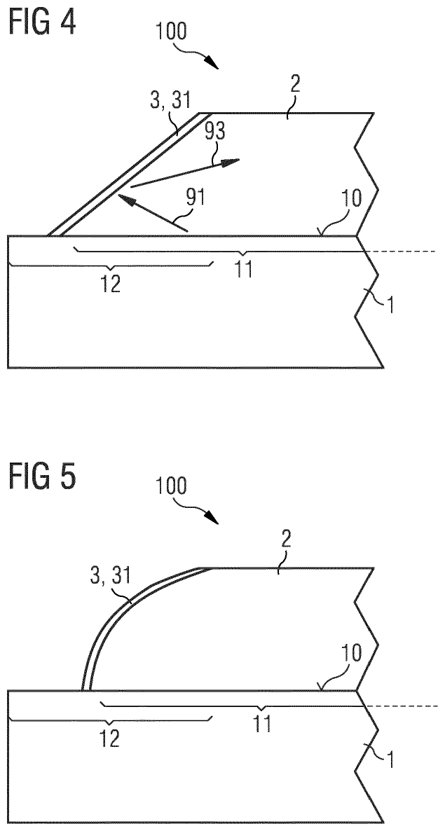

FIG. 4 shows a schematic illustration of light-emitting semiconductor device according to a further embodiment,

FIG. 5 shows a schematic illustration of light-emitting semiconductor device according to a further embodiment,

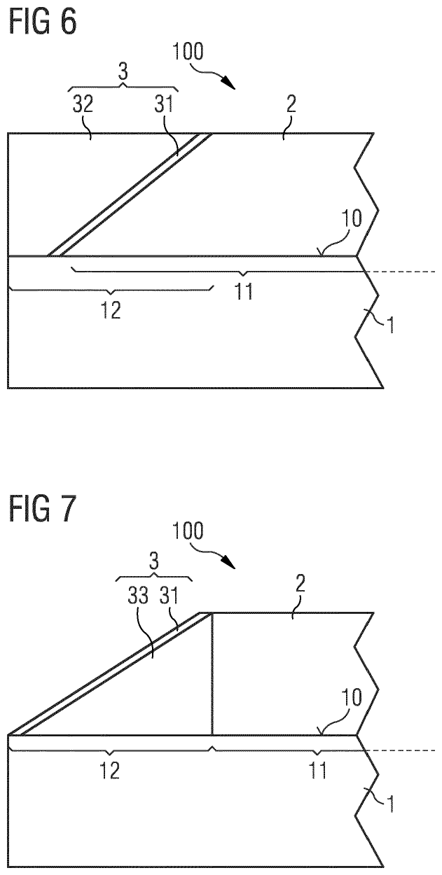

FIG. 6 shows a schematic illustration of light-emitting semiconductor device according to a further embodiment, and

FIG. 7 shows a schematic illustration of light-emitting semiconductor device according to a further embodiment.

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

FIGS. 1A and 1B show a sectional view of an embodiment of a light-emitting semiconductor device 100, respectively. FIG. 1B shows a section of the light-emitting semiconductor device 100 in FIG. 1A to illustrate some of the features. The following description refers equally to FIGS. 1A and 1B.

The light-emitting semiconductor device 100 comprises a light-emitting semiconductor chip 1. The light-emitting semiconductor chip 1 comprises a semiconductor layer sequence with an active region for generating first light 91. The light-emitting semiconductor chip 1 furthermore comprises a main surface 10 which is arranged perpendicular to the growth direction of the semiconductor layer sequence and which comprises a radiation-outcoupling surface via which the first light 91 generated during operation in the semiconductor chip 1 is emitted. The main surface 10 and thus the semiconductor chip 1 can preferably have an area greater than or equal to 0.1 mm² and less than or equal to 2 mm².

In particular, the semiconductor layer sequence of the light-emitting semiconductor chip 1 can, in the form of a plurality of semiconductor layers, be grown on a growth substrate by means of an epitaxy process, for example metal organic vapor phase epitaxy (MOVPE) or molecular beam epitaxy (MBE), and provided with electrical contacts. By singulation of the growth substrate with the grown semiconductor layer sequence, a plurality of the semiconductor chips can be provided. Furthermore, the semiconductor layer sequence can be transferred to a carrier substrate before singulation and the growth substrate can be thinned or completely removed. Such semiconductor chips, which have a carrier substrate instead of the growth substrate as substrate, can also be called thin-film semiconductor chips. The elements applied to the semiconductor chip 1 and described below can be applied before or after the singulation.

The semiconductor layers are arranged on top of each other along an arrangement direction in a vertical direction given by the growth direction. Perpendicular to the vertical direction, the layers of the semiconductor layer sequence each have a main extension plane corresponding to the main extension plane of the main surface 10. Directions parallel to the main extension plane of the main surface 10 and thus perpendicular to the vertical direction are hereinafter referred to as lateral directions.

In the embodiment shown, the radiation-outcoupling surface of the light-emitting semiconductor chip 1, if applicable with the exception of one or more electrical contacts, is particularly preferably the entire main surface 10 of the light-emitting semiconductor chip 1. Furthermore, the semiconductor chip 1 comprises a rear side opposite the main surface 10 and therefore opposite the radiation-outcoupling surface, which can form a mounting surface with which the light-emitting semiconductor chip 1 can be arranged on a carrier, for example. The main surface 10 and the rear side can be connected to each other via chip side surfaces that delimit the light-emitting semiconductor chip 1 in the lateral direction. Together with the side surfaces, the main surface 10 forms an edge that delimits the main surface 10 in the lateral direction. Regions of the main surface 10 which comprise at least a part of the edge of the main surface 10 can also be called edge regions here and in the following.

Electrical contacts of the light-emitting semiconductor chip 1 can be located on different sides of the semiconductor layer sequence or even on the same side. For example, the light-emitting semiconductor chip 1 can comprise an electrical contact in the form of a solderable or adhereable contact area on a side of a substrate opposite the semiconductor layer sequence. On a side of the semiconductor layer sequence opposite to such a substrate, a further contact area can be formed, for example in the form of a so-called bond pad for contacting by means of a bond wire. Furthermore, the light-emitting semiconductor chip 1 can have the electrical contact areas on the same side, for example as solderable or adhereable contact areas, and can be embodied as a so-called flip chip which can be mounted with the contact areas on a carrier, for example a circuit board, a printed circuit board or a light-emitting diode housing. In addition, the light-emitting semiconductor chip 1 can also have two contact areas formed as bond pads on the same side of the semiconductor layer sequence.

In particular, the active region can comprise an active layer in which light is generated during operation. The semiconductor layer sequence can have as active region for example a conventional pn junction, a double heterostructure, a single quantum well structure (SQW structure) or a multiple quantum well structure (MQW structure). In addition to the active region, the semiconductor layer sequence can comprise further functional layers and functional regions, such as p- or n-doped charge carrier transport layers, i.e. electron or hole transport layers, undoped or p- or n-doped confinement, cladding or waveguide layers, barrier layers, planarization layers, buffer layers, protective layers and/or electrodes as well as combinations thereof. In addition, one or more mirror layers can be deposited on a side of the semiconductor layer sequence facing away from a growth substrate. Furthermore, additional layers, such as buffer layers, barrier layers and/or protective layers can also be arranged perpendicular to the growth direction of the semiconductor layer sequence, for example around the semiconductor layer sequence, i.e. on side surfaces of the semiconductor layer sequence.

Depending on the choice of material for the semiconductor layer sequence described in the general section above, the light-emitting semiconductor chip 1 can emit first light in a desired first wavelength range during operation, which can lie in a visible spectral range, for example. Purely as an example, the semiconductor chip 1 shown here generates first light in a blue wavelength range during operation.

The structures described here concerning the light-emitting semiconductor chip and in particular the semiconductor layer sequence, the active region and the other functional layers and regions are known to the expert in particular with regard to their construction, function and structure and are therefore not shown for the sake of clarity and are not explained in detail here.

The light-emitting semiconductor device 100 also comprises a wavelength conversion layer 2, which is located on the main surface 10. The wavelength conversion layer 2 is applied to a first sub-region 11 of the main surface and in particular to the radiation-outcoupling surface in such a way that first light 91 generated by the light-emitting semiconductor chip 1 during operation can be radiated directly onto the wavelength conversion layer 2. In other words, the wavelength conversion layer 2 is arranged on the first sub-region 11. As shown in the present embodiment, the wavelength conversion layer 2 can be arranged at a distance from the main surface 10 and thus at a distance from the radiation-outcoupling surface.

As described above in the general part, the wavelength conversion layer 2 comprises one or more wavelength conversion materials and is embodied and intended to convert at least part of the first light 91 into second light 92 in a second wavelength range different from the first wavelength range of the first light 91. In particular, the second wavelength range can comprise spectral components at longer wavelengths than the first wavelength range. Purely as an example, the second light can also have spectral components in a red to green wavelength range, so that a mixture of the first and second light 91, 92, which is emitted by the light-emitting semiconductor device 100 during operation, preferably results in white light.

The wavelength conversion layer 2 can comprise a transparent matrix material, which can be formed by a plastic such as silicone, a glass, a ceramic material or a combination thereof, in which the wavelength conversion material or materials are embedded. A so-called phosphor platelet thus formed can be prefabricated and thus self-supporting. Furthermore, the wavelength conversion material(s) can be applied to a transparent substrate, for example comprising or be made of glass and/or plastic. In the case of one or more ceramic wavelength conversion materials, the wavelength conversion layer 2 can also be a self-supporting ceramic component.

As can be seen in FIGS. 1A and 1B, the wavelength conversion layer 2 does not cover the entire main surface 10, and in particular not the entire radiation-outcoupling surface of the light-emitting semiconductor chip 1. Rather, the first sub-region 11, which is covered by the wavelength conversion layer 2 and from which the light-emitting semiconductor chip 1 can emit first light 91 directly onto the wavelength conversion layer 2, is spaced from the edge of the main surface 10 and thus does not comprise an edge region of the main surface 10.

The light-emitting semiconductor device 100 also comprises an optical feedback element 3, which is applied to the main surface 10. In particular, the optical feedback element 3 can be applied directly to the main surface 10 and thus also directly to the radiation-outcoupling surface, for example by means of a suitable bonding layer such as an adhesive layer. The optical feedback element 3 is applied to a second sub-region 12 of the main surface 10 and in particular of the radiation-outcoupling surface, which is at least partially different from the first sub-region 11, so that the second sub-region 12 and thus also the optical feedback element 3 do not completely cover the main surface 10.

In particular, the second sub-region 12 can be adjacent to the first sub-region 11 and can be that part of the main surface 10 and thus of the radiation-outcoupling surface through which first light cannot be radiated directly onto the wavelength conversion layer 2. The second sub-region 12 is particularly preferred, as can be seen in FIGS. 1A and 1B, an edge region of the main surface 10, the second sub-region 12 completely surrounding the first sub-region 11 in the embodiment shown. In a view of the main surface 10 along the vertical direction, the second main surface 12 and correspondingly the optical feedback element 3 form a frame around the first sub-region 11. Particularly preferably, the first and second sub-regions 91, 92 together can form the main surface 10. The main surface 10 can thus be formed completely by the first and second sub-regions 11, 12, so that the main surface 10 is completely covered by the combination of the wavelength conversion layer 2 and the optical feedback element 3.

In particular, the wavelength conversion layer 2 and the optical feedback element 3 do not or only slightly protrude in lateral direction beyond the main surface 10 of the light-emitting semiconductor chip 1. The light-emitting semiconductor chip 1, the wavelength conversion layer 2 and the optical feedback element 3 form, optionally with further layers or elements such as, for example, connecting layers, a self-supporting, coherent component whose lateral extension is determined at least substantially by the lateral extension of the light-emitting semiconductor chip 1.

The optical feedback element 3 is embodied in such a way that first light 91, which is emitted from the second sub-region 12 or which is emitted from the first sub-region 11 not into the wavelength conversion layer 2 but into the optical feedback element 3, is deflected in the direction of the radiation-outcoupling surface and/or in the direction of the wavelength conversion layer 2, as indicated in FIG. 1B with the arrows 93 in the form of deflected first light. Thus, first light is available for conversion or photon recycling.

At the same time, the luminance is increased in the first sub-region 11, which is smaller than the total main surface 10. Thus, the light-emitting semiconductor device 100 comprises a smaller luminous surface with a higher luminous density and a more homogeneous luminous density distribution compared to conventional conversion light-emitting diode chips.

The optical feedback element 3 can be embodied for angle-selective reflection, for example as a diffractive optical element and/or as a photonic crystal, or can comprise such an optical element.

As an alternative to the arrangement of the wavelength conversion layer 2 on the optical feedback element 3 shown in FIGS. 1A and 1B, and thus spaced from the main surface 10, the wavelength conversion layer 2 can also be arranged directly on the main surface 10 and thus also directly on the radiation-outcoupling surface in the first sub-region 11 of the main surface 10, as shown in a further embodiment for a light-emitting semiconductor device 100 in FIG. 2. “Directly arranged” can also include an arrangement and attachment by means of a suitable bonding layer, for example in the form of an adhesive layer. Alternatively, the wavelength conversion layer 2 can also be formed in the form of a casting or by another application method in the first sub-region 11 on the main surface 10.

The following figures show further embodiments for light-emitting semiconductor devices 100 in sectional view corresponding to FIG. 1B. The description of these embodiments is essentially limited to the differences to the respective previous embodiments.

The optical feedback element 3 of the light-emitting semiconductor device 100 of the embodiment shown in FIG. 3 is embodied as a gradient optic in the form of a so-called GRIN lens (GRIN: “gradient index”), in which the first light 91 is deflected by a varying refractive index.

In FIG. 4, the optical feedback element 3 comprises a reflective optical element comprising a reflecting layer 31 inclined to a surface normal of the main surface 10. For this purpose, the wavelength conversion layer 2 comprises correspondingly inclined side surfaces on which the reflecting layer 31 is arranged. The reflecting layer 31, which can be applied to the side surfaces of the wavelength conversion layer 2 in the form of a coating, can, for example, comprise a metal and/or a dielectric layer sequence, in particular in the form of a Bragg mirror, or can be formed thereof.

FIG. 5 shows a light-emitting semiconductor device 100 according to a further embodiment, in which the reflecting layer 31, which forms the optical feedback element 3, is not planar but curved in comparison to the previous embodiment.

Accordingly, the lateral surfaces of the wavelength conversion layer 2 are also correspondingly curved. The curvature can be parabolic, hyperbolic, elliptical or a combination thereof. Depending on the desired radiation characteristic, the curvature can also vary locally.

In comparison with the embodiments in FIGS. 4 and 5, the light-emitting semiconductor device 100 according to a further embodiment shown in FIG. 6 comprises an optical feedback element 100, which comprises a material 32 on the side of the reflecting layer 31 facing away from the wavelength conversion layer 2, which for example can comprise or be a plastic, a ceramic and/or a glass. Since the reflecting layer 31 is located between the material 32 and the wavelength conversion layer 2, the material 32 can be selected independently of its optical properties. For example, the reflecting layer 31 can be applied and fixed to the material 32. The optical feedback element 3 formed in this way can be prefabricated and placed and fixed as a self-supporting, frame-shaped element on the semiconductor chip 1 and laterally on the wavelength conversion layer 2.

FIG. 7 shows a further embodiment of a light-emitting semiconductor device 100 in which the wavelength conversion layer 2 comprises vertical side surfaces as in the embodiments of FIGS. 1A to 3, while the optical feedback element 3 comprises a reflecting layer 31 as explained in connection with FIGS. 4 to 6. In order to obtain an inclined orientation of the reflecting layer 31 as shown in FIG. 7 purely as an example, the optical feedback element 3 comprises a transparent material 33 adjacent to the side surfaces of the wavelength conversion layer 2 on which the reflecting layer 31 is deposited. The transparent material can, for example, comprise or be a plastic such as an epoxy and/or a glass. Alternatively, instead of a transparent material, there can also be, for example, a suitably shaped optical element which forms, for example, a gradient optic as described in connection with FIG. 3 or another optical element described in connection with the previous embodiments.

The features and embodiments described in connection with the figures can also be combined with one another according to further embodiments, even if not all such combinations are explicitly described. Furthermore, the embodiments described in connection with the figures can alternatively or additionally have further features according to the description in the general part.

The invention is not limited by the description based on the embodiments to these embodiments. Rather, the invention includes each new feature and each combination of features, which includes in particular each combination of features in the patent claims, even if this feature or this combination itself is not explicitly explained in the patent claims or embodiments.

### REFERENCE NUMERALS

1 light-emitting semiconductor chip
10 main surface
11 first sub-region
12 second sub-region
2 wavelength conversion layer
3 optical feedback element
31 reflecting layer
32 material
33 transparent material
91 first light
92 second light
93 deflected first light
100 light-emitting semiconductor device

1. A light-emitting semiconductor device, comprising:
a light-emitting semiconductor chip having a main surface comprising a radiation-outcoupling surface via which, during operation, a first light in a first wavelength range is emitted,
on a first sub-region of the main surface, a wavelength conversion layer for converting at least part of the first light into second light in a second wavelength range different from the first wavelength range, and
an optical feedback element directly on a second sub-region of the main surface adjacent to the first sub-region,
wherein the optical feedback element deflects first light emitted from the second sub-region towards the radiation-outcoupling surface and/or towards the wavelength conversion layer,
wherein the optical feedback element comprises a gradient optics or a reflective optical element, wherein the reflective optical element comprises a reflecting layer which is inclined with respect to a surface normal of the main surface and/or which is curved.

2. The semiconductor device according to claim 1, wherein the second sub-region is an edge region of the main surface.

3. The semiconductor device according to claim 1, wherein the second sub-region completely surrounds the first sub-region.

4. The semiconductor device according to claim 1, wherein the first and second sub-regions form the main surface.

5. The semiconductor device according to claim 1, wherein the wavelength conversion layer is deposited directly on the first sub-region of the main surface.

6. The semiconductor device according to claim 1, wherein the wavelength conversion layer is laterally directly adjoins the optical feedback element.

7. The semiconductor device according to claim 1, wherein the reflective optical element comprises a transparent material on which the reflecting layer is arranged.

8. The semiconductor device according to claim 1, wherein the main surface comprises an area of less than or equal to 2 mm².

9. The semiconductor device according to claim 1, wherein the wavelength conversion layer and the optical feedback element do not protrude laterally beyond the main surface.
